(19) United States
(12) Patent Application Publication
(10) Pub. No.: US 2021/0282272 A1
(43) Pub. Date: Sep. 9, 2021

(54) SURFACE MOUNT TECHNOLOGY RELIABILITY MONITORING SYSTEM

(71) Applicant: BAE Systems Controls Inc., Endicott, NY (US)

(72) Inventors: Kevin E. Hill, Vestal, NY (US); John K. Khadjadorian, Apalachin, NY (US); Cort D. Lansenderfer, Tafton, PA (US); Russell M. Petrosky, Johnson City, NY (US)

(73) Assignee: BAE Systems Controls Inc., Endicott, NY (US)

(21) Appl. No.: 17/261,740

(22) PCT Filed: Aug. 13, 2018
(86) PCT No.: PCT/US2018/046445

§ 371 Date: Jan. 20, 2021

(51) Int. Cl. H05K 3/34; G01R 31/71; H01L 23/498; H05K 1/11

(52) U.S. Cl. CPC H05K 3/3436; G01R 31/71; H01L 23/49838; H01L 23/49883; H05K 2201/0154; H05K 2201/10734; H05K 2201/10378; H05K 2201/10689; H05K 1/111

(57) ABSTRACT

A ball grid array device includes a monitoring circuit of inactive solder joints and a processor such as a field programmable gate array (FPGA) or other processor capable of determining the open or closed status of the monitoring circuit. The monitoring circuit traverses one or more of the solder joints between components being joined, such as a printed circuit board and an integrated circuit device. In certain embodiments, the inactive solder joints may be located within regions of the ball grid array that are predisposed to failure, such as at the periphery or corners of the printed circuit board, or proximate to regions that experience a broad range of operating temperatures. The failure of a solder joint within the monitoring circuit can be used to schedule maintenance of the ball grid array device prior to failure of an active solder joint.

### BACKGROUND

The present disclosure relates generally to the field of electronics packaging and the interconnection of electronic components and more specifically to methods and systems for monitoring the mechanical and electrical integrity of electrical interconnects such as solder joints that are used to electrically connect various electronic structures.

Surface mount technologies are methods of fabricating electronic circuits where components are placed directly onto the surface of a printed circuit board. In contrast to traditionally routed circuits, surface mount technologies enable automated production and soldering, which improves manufacturability and reliability of the resulting surface mount devices (SMDs). Example surface mount technologies include ball grid array (BGA), land grid array (LGA) and quad-flat packaging (QFP) such as quad-flat no-lead (QFN) packaging.

Ball grid array (BGA) electronic modules, for example, have become ubiquitous in the commercial electronics industry, and are used in the packaging of various devices. In certain applications, however, including aerospace, military, and satellite communications, BGA packaging may exhibit poor reliability in response to mechanical or thermomechanical stresses. Solder joint failures may lead to downtime for equipment and increase an end system's exposure to potentially unsafe or mission-ending equipment failures. The intrinsic rigidity of solder joints in a ball grid array, for instance, may be unable to accommodate mechanical stresses, including the differential expansion arising from mismatched coefficients of thermal expansion between adjacent components. One such example is a printed circuit board and a substrate supporting a chip to which the printed circuit board is electrically connected via the solder joints.

### SUMMARY

Notwithstanding recent developments, it would be advantageous to develop a screening methodology for detecting and/or predicting solder joint failures in BGA-based devices. According to various embodiments, within a ball grid array, a plurality of inactive solder joints are electrically interconnected to form a circuit that is monitored using a suitable processor such as a field programmable gate array (FPGA), i.e., central processing unit (CPU), or other processor capable of reporting open/closed loop status. The monitoring circuit traverses one or more solder balls between the components being joined. In certain embodiments, the inactive solder joints may be located within regions of the ball grid array that are predisposed to failure, such as at the periphery or corners of the printed circuit board, or proximate to regions that experience a broad range of operating temperatures. Failure of an inactive solder joint within the monitoring circuit is detected as an open signal, which is registered as an alarm foretelling the possibility of a pending failure of an active solder joint. Advantageously, the circuit of inactive solder joints in non-invasive and can be monitored in real-time during operation of the device.

According to several embodiments, a surface mount device includes a circuit board, an electronic device overlying the circuit board, a ball grid array disposed between the device and the circuit board, a first plurality of (active) solder joints within the ball grid array electrically coupling the electrical device with the circuit board, and a monitoring circuit comprising a second plurality of (inactive) solder joints within the ball grid array, the second plurality of solder joints being electrically isolated from the electrical device.

An example method of manufacturing a surface mount device includes forming a ball grid array between a circuit board and an electrical device overlying the circuit board, where a first plurality of solder joints within the ball grid array electrically couples the electrical device with the circuit board, and forming a monitoring circuit comprising a second plurality of solder joints within the ball grid array, the second plurality of solder joints being electrically isolated from the electrical device and electrically coupled to the monitoring circuit.

A method of monitoring such a surface mount device may include passing a source current or a source voltage through the monitoring circuit, measuring a return current or a return voltage, and determining if the return current or the return voltage is within predetermined parameters.

### BRIEF DESCRIPTION OF SEVERAL VIEWS OF THE DRAWINGS

The following detailed description of specific embodiments of the present disclosure can be best understood when read in conjunction with the following drawings, where like structure is indicated with like reference numerals and in which:

FIG. 1A is a top-down plan view of a conventional printed circuit board including an array of solder balls;

FIG. 1B is a cross-sectional view of the printed circuit board and ball grid array of FIG. 1A;

FIG. 2 is a cross-sectional schematic view of a ball grid array package including an integrated circuit (IC) die in electrical contact with a printed circuit board;

FIG. 3 is a cross-sectional schematic view of a ball grid array package showing failure of a solder joint within the ball grid array;

FIG. 4 is a schematic illustration of a ball grid array including inactive solder balls according to various embodiments;

FIG. 5A is a top-down plan view schematic of a monitoring circuit configured to assess the integrity of solder joints between an IC die and a printed circuit board according to various embodiments;

FIG. 5B is a flow chart detailing an example monitoring algorithm for the monitoring circuit of FIG. 5A;

FIG. 6 shows a ball grid array package including plural inactive solder ball-containing monitoring circuits according to certain embodiments;

FIG. 7 depicts a monitoring circuit within a ball grid array located between an interposer board and a printed circuit board;

FIG. 8A depicts a monitoring circuit including a single, electrically shorted inactive solder ball according to certain embodiments;

FIG. 8B shows a flow chart detailing an example monitoring algorithm for the monitoring circuit of FIG. 8A;

FIG. 9A shows a ball grid array package including a monitoring circuit having plural shorted inactive solder balls according to further embodiments; and

FIG. 9B is a flow chart detailing an example monitoring algorithm for the monitoring circuit of FIG. 9A.

### DETAILED DESCRIPTION

Reference will now be made in greater detail to various embodiments of the subject matter of the present disclosure, some embodiments of which are illustrated in the accompanying drawings. The same reference numerals will be used throughout the drawings to refer to the same or similar parts.

Integrated circuits (ICs) are typically contained within a package that is mounted to a circuit board, i.e., printed circuit board (PCB). The package customarily includes conductive leads or pins that are soldered to the printed circuit board and connected to the integrated circuit by a lead frame. Electrical connections between the package and the printed circuit board may be made using a ball grid array (BGA). A ball grid array includes a plurality of solder balls disposed at the interface between the package and the printed circuit board. The facing surfaces of the BGA package and the PCB each typically include a number of conductive traces and accompanying solder pads. The IC chip within the package may be connected to the solder pads by wire bonds and electrically coupled to the solder balls and thereby through conductive traces routed across the PCB.

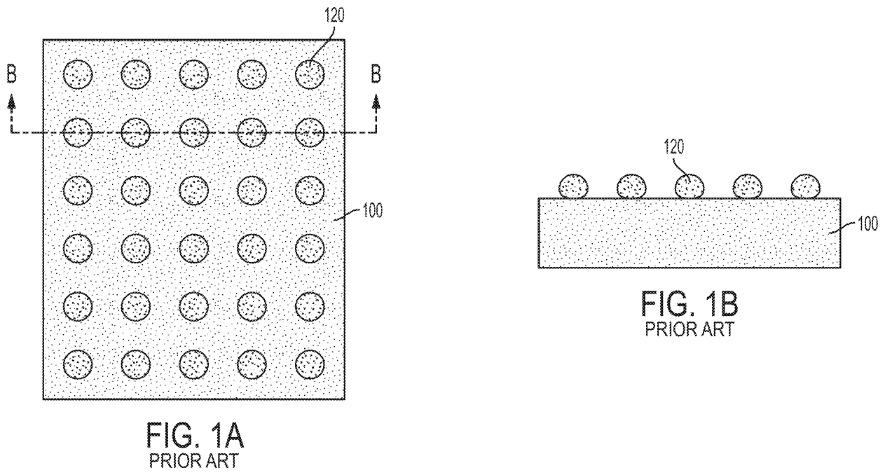

Referring to FIG. 1A and FIG. 1B, shown schematically are top and cross-sectional views, respectively, of a printed circuit board 100 packaged with ball grid array (BGA) interconnects. An array of conductive solder balls 120 is formed over a top surface 100A of the circuit board 100, or may be integral to the ball grid array IC package. The solder balls 120 may include a solder composition and/or other conductive material. Example solder compositions include tin-based alloys, such as tin-silver-copper (SAC) compositions. The solder compositions may contain lead or be lead-free.

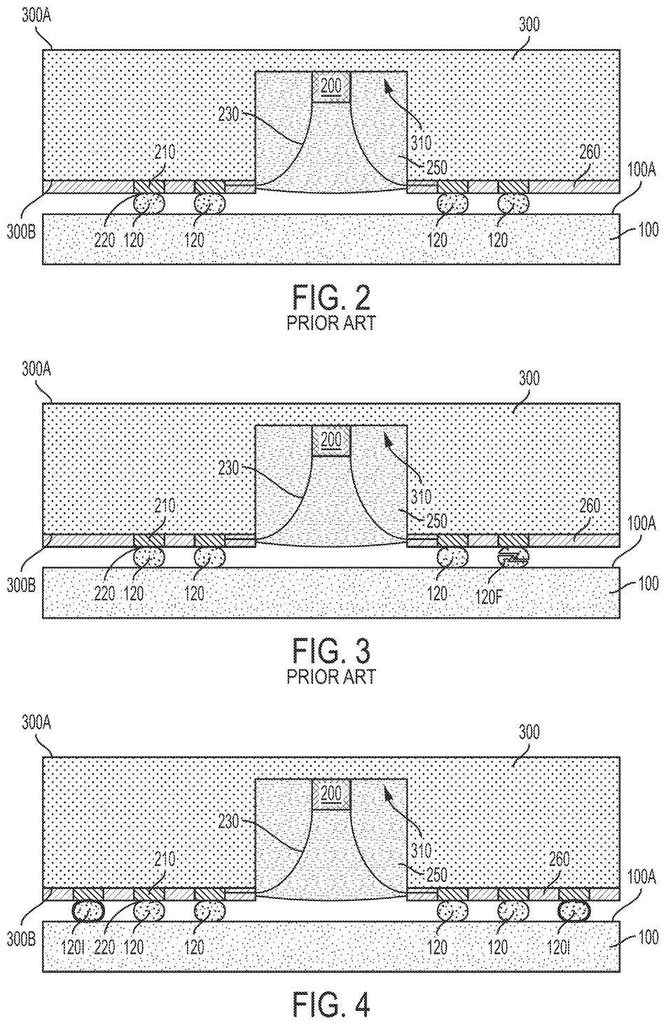

Referring to FIG. 2, illustrated is a detailed cross-sectional view of an example “cavity down” BGA package. The package includes a device such as an integrated circuit (IC) die 200 overlying and in electrical contact with a printed circuit board 100. The IC die 200 may have memory or logic functionality, for example, and may be a flash memory chip, processor, embedded controller, or a further type of integrated circuit device.

The BGA package includes a supporting substrate 300, having an upper surface 300A and a lower surface 300B, with a recessed cavity 310 formed in the lower surface 300B. The substrate 300 may be formed from any suitable dielectric material, including a polyimide polymer or a glass-reinforced epoxy laminate, such as FR-4. The semiconductor integrated circuit die 200 is affixed to the ceiling, i.e., upper surface, of the cavity 310 using, for example, a heat-dissipating, epoxy adhesive.

A patterned lead frame of an electrical conductor, e.g., copper metal, is formed over the lower surface 300B of the substrate 100. The lead frame defines a plurality of conductive traces 210 that extend outwardly from the cavity 310. Each trace 210 terminates at a bond pad 220, which is metallurgically wetted to a respective solder ball 120. The traces 210 provide an electrical connection between one of the solder balls 120 and a corresponding bond wire 230 emanating from the IC die 200.

At least a portion of the die 200, including bond wires 230, may be encapsulated with an encapsulation layer 250 that fills the cavity 310. By way of example, the encapsulation layer 250 may include a thermoset epoxy molding compound.

In certain embodiments, a patterned solder mask 260 is disposed over the bottom surface 300B of the substrate. The solder mask 260 has a plurality of openings that expose bond pads 220. Each of the solder balls 120 is connected to a contact point of the printed circuit board 100. During assembly, a plurality of solder balls 120 located on the upper surface 100A of printed circuit board 100 are placed into the solder mask openings and onto the bond pads 220. A solder flux is typically applied to the bond pads 220 prior to the placement of the solder balls 120 into the openings.

As known to those skilled in the art, a heating (reflow) step is used to at least partially melt the solder balls 120 and form physical, conductive contacts between the bond pads 220 and the printed circuit board 100. The solder mask 260 is configured to restrict lateral flow of the solder and avoid short circuits between neighboring contacts. The solder balls then re-harden during a subsequent cooling step.

Referring to FIG. 3, a cross-sectional view of an example BGA package depicts a solder joint failure, wherein unaccommodated stresses encountered, for example, during operation or handling of the package, result in the fracture of solder ball 120F. The attendant loss of electrical connectivity between the printed circuit board 100 and the die 200 through fractured solder ball 120F may adversely impact reliability and performance of the device.

It is believed that solder joints can develop cracks from cumulative stress exposure. Cracks may propagate between the BGA package and the solder balls, or between the solder balls and the PCB. A crack can initially cause partial separation of a solder ball 120 from either the BGA package or the PCB. Once a crack forms, progressive stresses can lead to fracture, which involves the complete separation of a solder ball that breaks the point of contact between an integrated circuit and a printed circuit board.

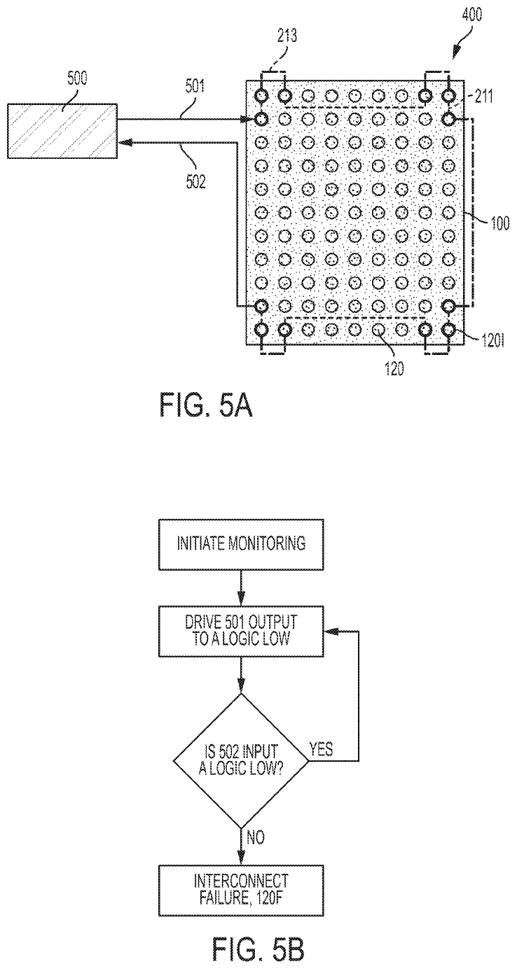

According to various embodiments, and with reference to FIG. 4, a plurality of solder balls 120I not forming an electrical connection between active components of the printed circuit board 100 and the integrated circuit die 200 are incorporated in the BGA architecture. These inactive solder balls 120I are electrically stitched together to form a monitoring circuit 400 as shown in FIG. 5A, that traverses back and forth between the printed circuit board 100 and the substrate 300. According to various embodiments, the composition and structure of the inactive solder balls 120I forming monitoring circuit 400 may be the same as the composition and structure of active solder balls 120. As used herein, an “inactive” solder ball is electrically isolated from die 200.

A central processing unit (CPU), such as a field programmable gate array (FPGA) or other processor 500 adapted to detect the electrical continuity of the monitoring circuit 400 may be disposed on either the printed circuit board 100, within the integrated circuit die 200, or on the substrate 300, e.g., within a ball-grid array device.

According to various embodiments, in addition to the monitoring circuit 400, processor 500 may be configured to monitor the connection integrity of other devices and structures (not shown) connected to the printed circuit board 100. Such additional devices/structures may include integrated circuits, daughter cards, and various connections including solder joints, traces, connectors and backplane connections located in or on the printed circuit board 100 or internal to the devices being monitored.

During operation, the FPGA sources an electrical current or voltage as an output signal that traverses the connected elements within the monitoring circuit 400. The FPGA 500, which is located as the last element in the closed circuit, monitors the continuity of the circuit by comparing the sourced current or voltage with the return current or voltage. When the sourced and returned values are equal, i.e., within predefined parameters, the circuit is considered good and no error is reported. In the event an element within the circuit experiences degraded connectivity, the circuit's integrity becomes compromised and the monitor logic within the FPGA 500 will detect a return value that is outside the accepted parameters. This causes the FPGA 500 to generate an error signal that can be read by a suitable controller. The error signal may be an internal register that is accessible by an external master controller, for example, or it may manifest on a visible indicator such as an LED. The master controller in one example is a computing resource that can store the result, provide an alerting function or take affirmative action such as re-routing functionality or leveraging redundant capability. The master controller alerting can provide an audible or visual indication, such as a communication to an operator or an alert to a central processing center.

Without wishing to be bound by theory, solder joints typically degrade slowly as a function of time, temperature, voltage, and other environmental conditions. In this regard, and according to various embodiments, the FPGA 500 can perform monitoring at a rate that is greater than the rate at which most connections begin to fail. This enables the FPGA 500 to provide an early detection mechanism, which indicates when a connection within a component is about to fail or is beginning to fail prior to any manifestation of failure. For instance, the FPGA 500 can implement a configurable threshold such that the error signal is generated when a single failure is detected, or after the number of errors detected crosses the threshold. This early detection enables a more cost-effective preventative maintenance schedule to be employed. The threshold can be adjusted as additional diagnostic data is collected to refine the threshold from a diagnostic tool to a prognostic mechanism to predict failure.

In certain embodiments, the inactive solder balls 120I may be located within regions of the BGA package that experience an above average mechanical strain and/or an above average range of temperatures during operation. The location of the inactive solder balls 120I within the ball grid array may be determined empirically or through modeling.

In certain embodiments, a ball grid array may be characterized as a matrix having m rows (R) and n columns (C). As used herein, a “peripheral” solder ball is located within a first, second or third row of the matrix (e.g., R₁, R₂ or R₃), a third-from-last, penultimate or last row of the matrix (e.g., Rₘ₋₂, Rₘ₋₁ or Rₘ), a first, second or third column of the matrix (e.g., C₁, C₂ or C₃), or a third-from-last, penultimate or last column of the matrix (e.g., Cₙ₋₂, Cₙ₋₁ or Cₙ). A “corner” solder ball is located within both a peripheral row and a peripheral column.

Referring to FIG. 5A, inactive solder balls 120I may be located at corners of the BGA package. After affixing the package to the printed circuit board 100 via the ball grid array, inactive solder balls 120I together with traces 211 disposed on the upper surface 100A of the printed circuit board, and traces 213 disposed on the lower surface 300B of the substrate 300 form monitoring circuit 400. In one example the traces 213 are printed wiring board (PWB) traces and the internal traces 211 are traces on the interposer substrate. Inactive solder balls 120I, PCB traces 211, substrate traces 213 and processor 500 form a closed loop that is electrically isolated from active traces 210 and IC die 200. While shown at the periphery, it will be appreciated that other patterns such as circular or diagonal can be used to provide monitoring using the inactive solder balls and traces.

During device operation, processor 500 may continuously or intermittently assess the continuity of monitoring circuit 400. Detection by processor 500 of an open circuit within the monitoring circuit 400 is indicative of failure of at least one inactive solder ball 120I, which may be used to schedule maintenance or retirement of the device prior to a system-interrupting failure. That is, the failure of a solder joint 120I within monitoring circuit 400 may occur prior to the failure of an active solder joint 120, thus providing advanced warning of product fatigue or obsolescence.

Referring to FIG. 5B, a flow chart depicts an example monitoring algorithm for the monitoring circuit of FIG. 5A. During operation, the monitoring circuitry may be initiated when system power is applied or by using an external command In one example processor 500 drives output line 501 to a logic “0” state, while input line 502 is continuously monitored by the processor 500. This can be accomplished using different voltages and/or polarities. For example, a 3.3V, 1.8V or a voltage in-between. The system could drive the line high and use an external pull down resistor or if supported by the FPGA an internal pull down resistor. In the event a logic “1” is read, which indicative of a failed solder joint within the monitoring circuit 400, an alarm may be sent to a user and/or operation of the device may be halted.

It will be appreciated that although FIG. 5A depicts a single monitoring circuit 400 including three inactive solder balls 120I at each corner of the ball grid array, a system including plural monitoring circuits each having two or more inactive solder balls 120I is contemplated.

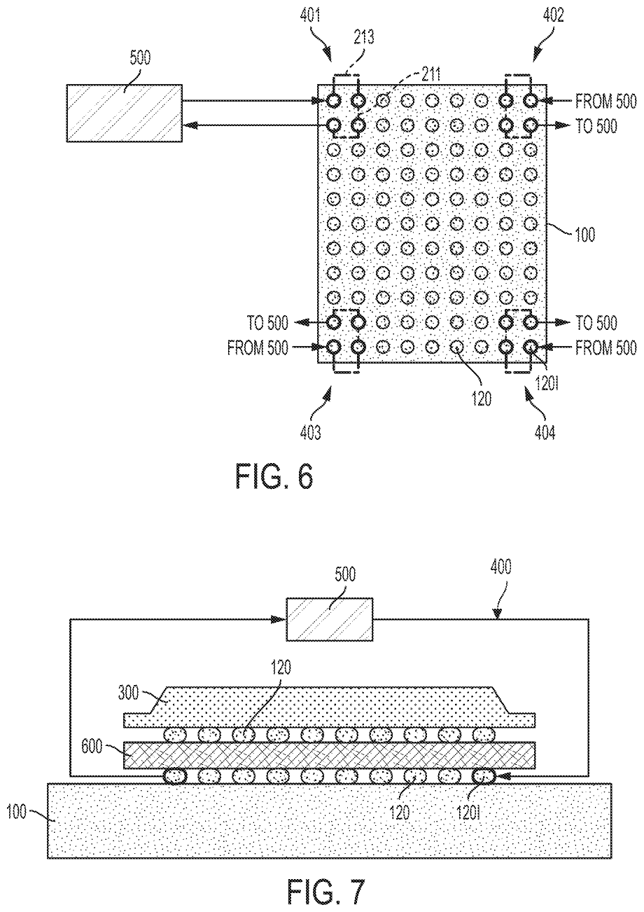

Referring to FIG. 6, for instance, shown is a BGA package according to a further embodiment having independent monitoring circuits 401, 402, 403, 404 each connected to processor 500. Plural monitoring circuits provide enhanced fidelity as to both the occurrence as well as the location of a failed solder joint. The method of operating the monitoring circuit 400 in the embodiment of FIG. 5A may be applied to the monitoring circuits 401, 402, 403, 404 of FIG. 6.

As will be appreciated, a monitoring circuit 400 including inactive solder balls 120I can be incorporated into a ball grid array that is used to connect various types of electronic components. According to various embodiments, the package construction can include single or multiple die and/or packaged components. By way of example, a monitoring circuit 400 can be incorporated into a ball grid array disposed (a) between a substrate 300 supporting an IC chip 200 and a printed circuit board 100, (b) between a substrate 300 supporting an IC chip 200 and an interposer board or, in the embodiment illustrated in FIG. 7, (c) between an interposer board 600 and a printed circuit board 100.

As used herein, an “interposer board” or “interposer” provides a structural and electrical interface between a semiconductor die and a printed circuit board. An interposer may be configured to alter the pitch of solder balls at a given surface, or to reroute a connection on a die to a different connection on a circuit board.

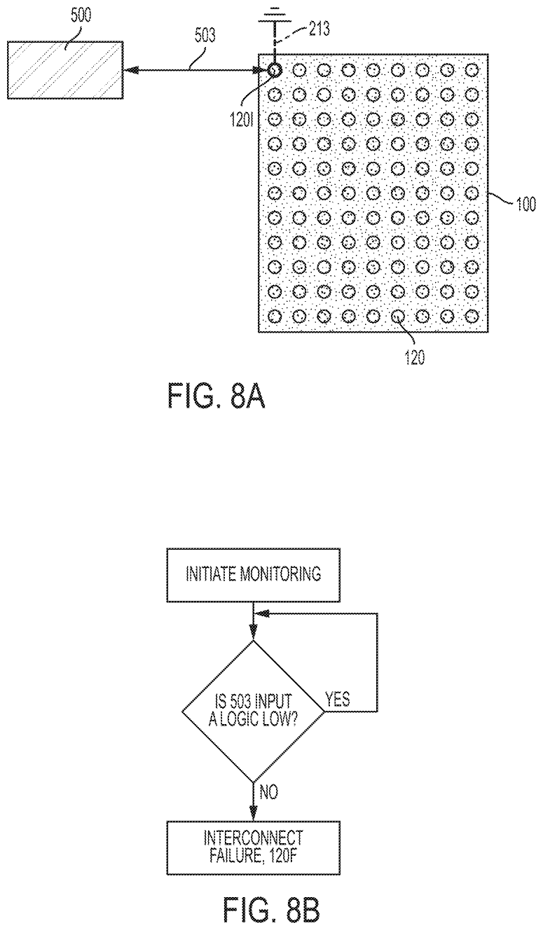

Referring to FIG. 8A, a monitoring circuit according to a further embodiment includes a single inactive solder ball 120I connected to a processor 500 proximate to printed circuit board 100 via line 503. The inactive solder ball 120I is also connected to electrical ground internal to the substrate 300. A voltage applied across the inactive solder ball 120I, i.e., between the printed circuit board 100 the substrate 300 is monitored to detect an intermittent or open connection. As shown in the illustrated embodiment, the grounded inactive solder ball 120I may be located at a periphery of the ball grid array, or elsewhere within the ball grid array. Such a configuration may be suitable for packages where a limited number of inactive solder balls are available.

During operation, as in previous embodiments, the monitoring circuitry may be initiated when system power is applied or by using an external command Processor 500 includes a pull-up termination that pulls line 503 to a logic “1” if the inactive solder ball 120I is fractured and electrical continuity through the inactive solder ball 120I is lost. In such an event, an alarm indicating an interconnect failure is registered.

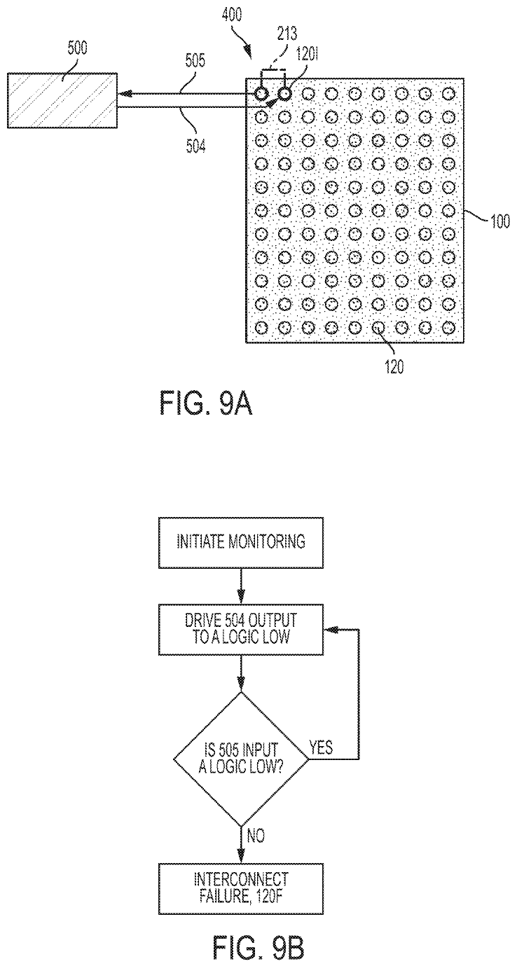

Referring to FIG. 9A, a BGA package according to a further embodiment includes monitoring circuit 400 including a pair of interconnected inactive solder balls 120I, each connected to a processor 500 and shorted via substrate 300. During operation, and with reference to the flow chart shown in FIG. 9B, a source current or a source voltage is passed through the monitoring circuit 400 via output 504. Detection by processor 500 via input 505 of an open circuit is indicative of failure of at least one inactive solder ball 120I.

The monitoring circuit of FIG. 9 can be implemented using any number of inactive solder balls 120I within the ball grid array, including peripheral and non-peripheral solder balls. Furthermore, additional such monitoring circuits may be provided, such as at further corners of the printed circuit board 100.

By way of example, the presently-disclosed methodology has been implemented on a double data rate synchronous dynamic random-access memory (DDR-SDRAM) integrated circuit interposer device. Inactive corner solder balls of the interposer were stitched together across the interposer-PCB interface and powered and monitored by an FPGA to provide the described benefit. By way of further example, the described monitoring circuitry may be implemented with conventional plastic encapsulating microcircuit (PEM) packaging, e.g., periphery wire bonded die, flip chip, etc.

According to various embodiments, the monitoring facilitates the detection of solder joint failures in a manner that does not impact the functionality of the active circuit or system. As a predictive technology, particularly in conjunction with safety-critical products, this avoids a decrease in operational time and allows preventative maintenance to occur prior to a functional failure. Because the detection method is real-time, it enables extended operational periods between scheduled maintenance or inspection, and/or the elimination of scheduled maintenance or inspection.

Although various embodiments have been described in connection with a ball grid array (BGA) electronic module, the described methods may be implemented in conjunction with other surface mount technologies, including land grid array (LGA) and quad-flat packaging (QFP), e.g., quad-flat no-lead (QFN) packaging.

As used herein, the singular forms “a,” “an” and “the” include plural referents unless the context clearly dictates otherwise. Thus, for example, reference to a “monitoring circuit” includes examples having two or more such “monitoring circuits” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a solder joint that comprises or includes a tin alloy include embodiments where a solder joint consists essentially of a tin alloy and embodiments where a solder joint consists of a tin alloy.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A surface mount device, comprising:
a circuit board;
an electronic device overlying the circuit board;
a ball grid array disposed between the device and the circuit board;
a first plurality of solder joints within the ball grid array electrically coupling the electrical device with the circuit board; and
a monitoring circuit comprising a second plurality of solder joints within the ball grid array, the second plurality of solder joints being electrically coupled and isolated from the electrical device.

2. The surface mount device of claim 1, wherein the monitoring circuit traverses at least one of the second plurality of solder joints.

3. The surface mount device of claim 1, wherein at least one of the second plurality of solder joints is located at a corner of the ball grid array.

4. The surface mount device of claim 1, wherein at least one of the second plurality of solder joints is located at a periphery of the ball grid array.

5. The surface mount device of claim 1, wherein the monitoring circuit further comprises a processor configured to source a predefined current or a predefined voltage through the second plurality of solder joints.

6. The surface mount device of claim 1, further comprising a substrate supporting the device and in physical contact with the ball grid array.

7. The surface mount device of claim 6, wherein at least one of the second plurality of solder joints is grounded to the substrate.

8. The surface mount device of claim 6, wherein a first plurality of electrical traces coupling at least two of the second plurality of solder joints are disposed on a surface of the substrate facing the circuit board, and a second plurality of electric traces coupling at least two of the second plurality of solder joints are disposed on a surface of the circuit board facing the substrate.

9. The surface mount device of claim 1, wherein the first and second plurality of solder joints comprise a lead-free solder composition.

10. The surface mount device of claim 1, further comprising an interposer between the device and the circuit board.

11. The surface mount device of claim 10, wherein the monitoring circuit comprises a first plurality of electrical traces disposed on a surface of the interposer facing the circuit board, and a second plurality of electric traces disposed on a surface of the circuit board facing the interposer, the second plurality of solder joints being disposed between the interposer and the circuit board.

12. A method of manufacturing a surface mount device, comprising:
forming a ball grid array between a circuit board and an electrical device overlying the circuit board, a first plurality of solder joints within the ball grid array electrically coupling the electrical device with the circuit board; and
forming a monitoring circuit comprising a second plurality of solder joints within the ball grid array, the second plurality of solder joints being electrically isolated from the electrical device and electrically coupled to the monitoring circuit.

13. The method of claim 12, further comprising forming a processor configured to source a predefined current or a predefined voltage through the monitoring circuit.

14. The method of claim 12, wherein the second plurality of solder joints are formed at a periphery of the ball grid array.

15. The method of claim 12, further comprising providing an alert when the monitoring circuit indicates a signal outside predefined parameters.

16. A method of monitoring the surface mount device of claim 1, comprising:
passing a source current or a source voltage through the monitoring circuit;
measuring a return current or a return voltage; and
determining if the return current or the return voltage is within predetermined parameters.

17. The method of claim 16, wherein the source current or the source voltage is provided by a field programmable gate array located on the circuit board.

18. The method of claim 16, wherein the source current or the source voltage is provided continuously during operation of the ball grid array device.
